(19) United States
(12) Patent Application Publication
(10) Pub. No.: US 2004/0000428 A1
(43) Pub. Date: Jan. 1, 2004

(54) Socketless package to circuit board assemblies and methods of using same

(76) Inventors: Mirng-Ji Lii, Chandler, AZ (US); Yuan-Liang Li, Chandler, AZ (US); Chia-Pin Chiu, Tempe, AZ (US)

Correspondence Address: SCHWEGMAN, LUNDBERG, WOESSNER & KLUTH, P.A., P.O. BOX 2938, MINNEAPOLIS, MN, 55402, US

(21) Appl. No.: 10/180,226

(22) Filed: Jun. 26, 2002

(51) Int. Cl. H01L 23/48

(52) U.S. Cl. 174/260; 257/727; 257/772; 257/778; 257/779; 257/737; 257/718; 174/267; 29/840

(57) ABSTRACT

A readily demountable socketless package to circuit board assembly is disclosed. The assembly includes a soft solder area and a metallic contact element, each located on copper pads. The metallic contact element is adapted to sufficiently penetrate the soft solder area to provide electrical contact. The metallic contact element can be either a sharp metallic element or a spring. Compressive force from a clamping mechanism ensures a secure electrical contact and adequate thermal performance.

### FIELD

This invention relates generally to package to circuit board assemblies, and in particular, the present invention relates to socketless package to circuit board assemblies.

### BACKGROUND

Conventional desktop and mobile system designs include an original equipment manufacturer (OEM) socket on a motherboard for pin grid array (PGA) packages, including flip chip PGA (FCPGA) packages. (FIG. 1). However, socket designs are expensive, add to assembly process complexity and can reduce electrical performance.

Additionally, because of increasingly higher performance and smaller socket BGA joint pitch requirements, a fine-pitch surface-mounted socket is often used. However, the fine-pitch surface mounted socket is a costly component and has only a limited ability to meet the increasingly finer pitch required for surface mounted PGA sockets. Land grid array (LGA) socket designs are also used, but have only a limited ability to meet high-pressure requirements.

Socketless surface mount technology (SMT) can be used for ball grid array (BGA) packages, including flip chip BGA (FCBGA) packages. Although SMT eliminates use of a socket, a SMT package is designed to be permanently mounted to a circuit board by the OEM. As a result, not only are the OEM build-time and costs high, a surface mounted package must be purchased together with the circuit board as a single unit. Thus, upgrading of the package is not possible without replacing the entire circuit board.

For the reasons stated above, there is a need in the art for a simple, yet effective means for meeting the increasing demands of higher-powered desktop and mobile systems.

### BRIEF DESCRIPTION OF THE DRAWINGS

FIG. 1 is a schematic illustration of a prior art socket-mounted package to circuit board assembly.

FIG. 2 is a schematic illustration of a socketless FCPGA package to circuit board direct assembly.

FIG. 2A is an enlarged view of the assembly in FIG. 2 showing spring contact elements built onto package pads in one embodiment of the present invention.

FIG. 3 is a plot of applied force versus displacement for indium solder.

FIG. 4A is a schematic illustration of an integrated package pad design in one embodiment of the present invention.

FIG. 4B is a schematic illustration of a spring contact element unit in one embodiment of the present invention.

FIG. 5 is a schematic illustration of a socketless FCBGA package to circuit board direct contact assembly.

FIG. 5A is an enlarged view of the assembly in FIG. 5 showing multiple types of spring contact elements built onto circuit board pads in alternative embodiments of the present invention.

FIG. 6 is a schematic illustration of a socketless FCLGA package to circuit board direct contact assembly.

FIG. 6A is an enlarged view of the assembly in FIG. 6 showing sharp metallic features built onto circuit board pads in alternative embodiments of the present invention.

FIG. 7 is a schematic illustration of a circuit board showing additional types of sharp metallic features built onto circuit board pads in yet other alternative embodiments of the present invention.

### DETAILED DESCRIPTION

Socketless package to circuit board assemblies and methods of using same are disclosed. The following description and the drawings illustrate specific embodiments of the invention sufficiently to enable those skilled in the art to practice it. Other embodiments may incorporate structural, logical, electrical, process, and other changes. Examples merely typify possible variations. Individual components and functions are optional unless explicitly required, and the sequence of operations may vary. Portions and features of some embodiments may be included in or substituted for those of others. The scope of the invention encompasses the full ambit of the claims and all available equivalents.

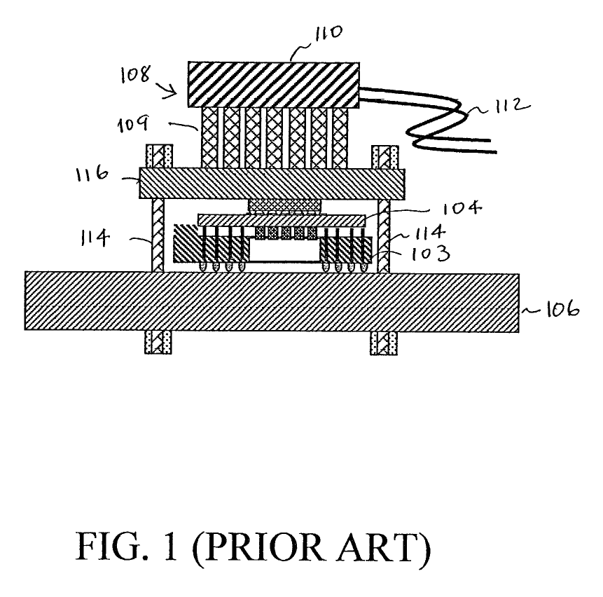

FIG. 1 provides a cross-sectional view of a prior art printed circuit assembly 102 that includes an OEM socket 103 designed to interconnect a PGA package 104, such as a FCPGA package, to a printed circuit board, such as a motherboard 106. Situated above the package 104 in this particular prior art design is a heat sink 108 having an array of vertically-oriented fins 109, a fan 110 and connecting wires 112, as known in the art. The design further includes mechanisms to provide adequate compressive pressure to ensure robust electrical and thermal performance. In this embodiment, bolt joints 114 are used to provide compressive pressure between the motherboard and a base plate 116.

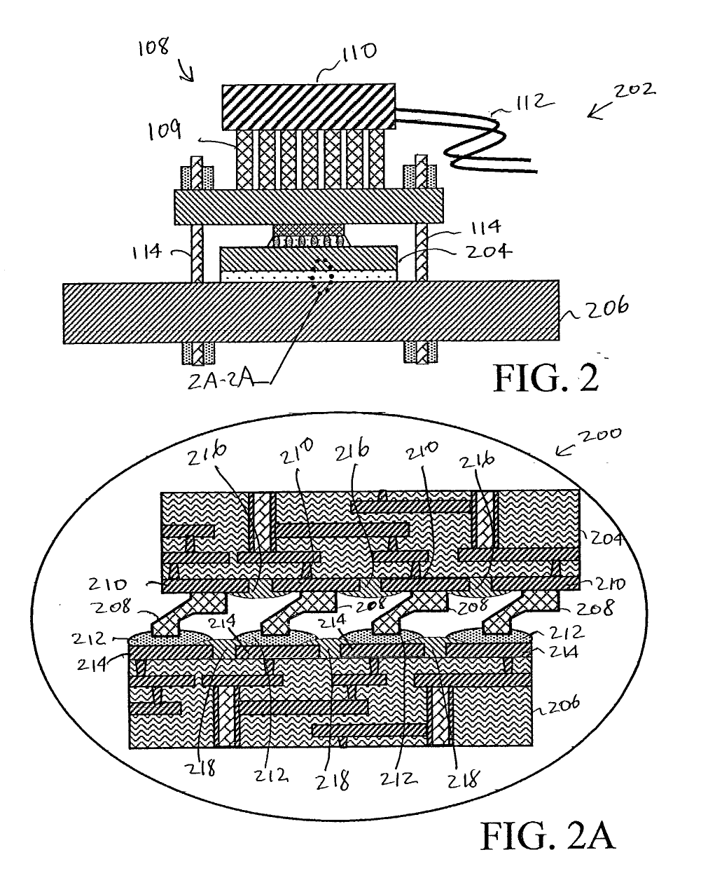

FIGS. 2 and 2A provide schematic illustrations of a socketless FCPGA package to printed circuit board direct contact assembly 200 (hereinafter “direct contact assembly”) within the present subject matter. As FIG. 2 shows, the direct contact assembly 200 is part of a printed circuit assembly 202. In this embodiment, a socketless FCPGA package 204 is designed for direct attachment to a printed circuit board, such as a motherboard 206, although any other type of package can be used, such as a FCBGA package, FCLGA package, and so forth. FIG. 2 further shows the heat sink 108 of FIG. 1, although the invention is not so limited. Any type of thermal solution can be used, including, but not limited to, a heat pipe, and so forth. Further, any suitable type of heat sink can be used having a variety of fin configurations, as is known in the art. In this embodiment, the compressive force apparatus is a bolt joint 114, although, again, the invention is not so limited. A heat sink clip, clamp mechanism or equivalent thermal solution attach mechanism can also be used.

In the embodiment shown in FIG. 2A, the socketless package 204 has spring contact elements 208 mounted, e.g., soldered, to package pads 210. Each spring contact element 208 further has a resilient metallic plating for providing a direct connection to the motherboard 206. In this embodiment, the motherboard 206 is modified to have areas of soft solder coating 212 applied to motherboard pads 214. The areas of soft solder coating 212 serve to provide superior electrical connections with the spring contact elements 208 of the package 204. The soft solder coating 212 can be applied, i.e., coated, on the motherboard pads 214 using a stencil having adequate aperture openings. Both the package 204 and motherboard 206 further have conventional package solder resist coatings 216 and motherboard solder resist coatings 218 as shown, to provide protection on active interconnects. The solder resist coatings 216 and 218 basically mask off and surface insulate those areas of a circuit where soldering is not desired or required.

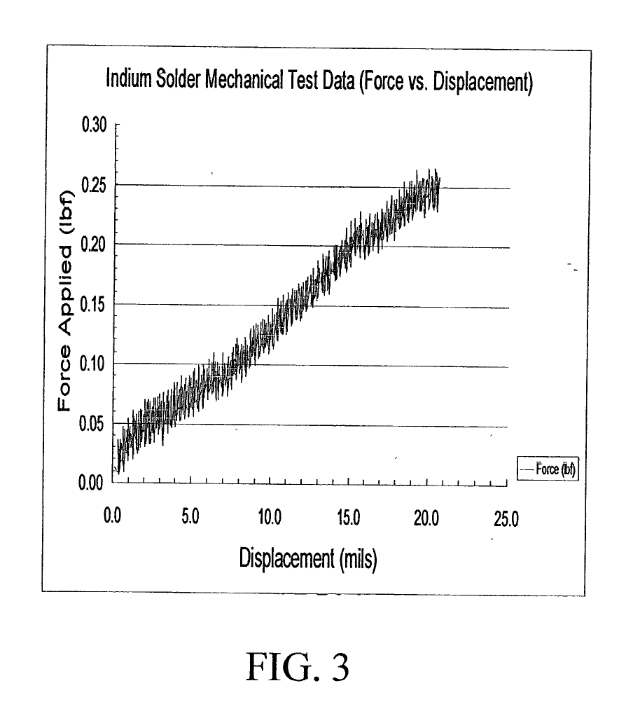

The spring contact elements 208 can take on any number of configurations or shapes as long as a secure connection to the soft solder areas 212 of the motherboard 206 can be made. The spring contact elements 208 are designed to deform or yield when pressure is applied, such as from a bolt joint 114. In one embodiment, the spring contact element 202 has a total length (x) and width (y) if about 0.25 to 0.76 mm (about 10 to 30 mil) and a total height (z) of about 0.25 to 0.6 mm (about 10 to 25 mil), although the invention is not limited to any particular geometry. The particular geometry shown in FIG. 2, however, assists in properly aligning the package with the motherboard pads 214 due to the presence of the extended arm. Such an offset design is able to compensate for misalignment between a package pad 210 and motherboard pad 214, which commonly occurs during fabrication. In one embodiment, misalignments of up to about 0.13 to 0.63 mm (about 5 to 25 mil) can be corrected with each spring contact element 202. Additionally, use of a spring as the contact element provides the necessary compressive force to contact the soft solder areas 212 to ensure low electrical resistance, such as between 8 to 10 milliohms or below. In another embodiment, the spring contact elements 208 are mounted or soldered directly onto the motherboard pads 214 (See FIG. 3). However, as a practical matter, in most embodiments it may be more feasible to have such an element added by the manufacturer of the package rather than the manufacturer of the motherboard.

The package pads 210 and motherboard pads 214 are conventional components typically made from copper or copper alloys. The spring contact elements 208 can be made from any suitable conductive metal. In one embodiment, the spring contact elements 208 are surface mounted copper or copper alloy spring contact elements having gold plating, although the invention is not so limited. Spring contact elements can be made of copper, copper alloys, nickel/iron alloys, silver alloys and so forth. Use of such materials helps to provide a low resistance and reduces voltage drop through the indium contact. The spring constant can vary, but generally needs to be stiffer than the stiffness of the soft solder (which is typically about 24.6 N/cm or 14 lb_{f}/in) so that the spring can penetrate the solder coating. In most embodiments, the spring constant is between about 35 and 52.5 Newtons (N)/cm (20 and 30 lb_{f}/in). Depending on the design, the loading force applied on a processor package with more than 500 contact spring elements by the compressive force source above, e.g., bolt joints, is between about 223 to 445 N (50 to 100 lb_{f}), which is more than adequate to achieve the five (5) mil penetration onto the soft solder for each spring contact element.

Any solder sufficiently penetrable by a metallic contact element can be used for the soft solder areas 212. In most embodiments, the material has a low melting temperature of between about 100 to 220° C., although soft solders having even higher melting points can be used. However, as the melting temperature increases, the material remains harder at room temperature, thus requiring stiffer and stronger metallic contact elements for penetration. In general, the solder used for the soft solder areas 212 has a yield strength of less than about 25 megapascals (mPa) with a targeted range of about five (5) to 20 MPa. Such materials include, but are not limited to, indium, indium/silver alloys, tin/indium alloys, tin/bismuth alloys, and so forth. Indium is a particularly good material for the soft solder areas 212 as it is very pliable and will give easily when a spring contact element 208 is pushed into it. Again, other materials that are known to be harder can also be used, including softer tin-lead alloys, but such solders may cause the components to be less readily demountable and are prone to surface oxidation. For example, the solder used for conventional solder bumps, i.e., tin or tin-based solder, has a melting temperature of about 183° C., making it less penetrable at room temperatures without the use of stiffer contact elements.

The assembly 200 shown in FIG. 2A ensures an appropriate electrical contact or interconnection between the components as well as adequate thermal performance. Essentially, the spring contact elements 208 can penetrate the soft solder coating 212 on the motherboard 206 sufficiently to provide the secure electrical contact. (See FIG. 3). Additionally, use of compressive pressure, such as with the bolt joint 114 shown in FIG. 2, enhances the robustness of system performance. In other embodiments, the additional pressure is provided by any known type of clamping mechanism or with heat sink clips. In this way, the socketless package 204 can be directly assembled onto the motherboard 206 without the use of an OEM socket.

FIG. 3 provides mechanical test data for indium solder, showing applied force in lbs-force (lb_{f}) versus displacement in mils. This experiment is intended to determine the amount of force required to penetrate the indium solder, i.e., typical indium solder mechanical properties.

A sheet of indium available commercially from any solder material manufacturer was used as the testing material. The indium specimen was approximately 3 cm by 3 cm. Testing was performed using a MTS 810 (material testing system) made by MTS, Inc. of Minneapolis, Minn. The MTS 810 system, with a needle-shaped test fixture, was used to imitate the spring elements discussed herein.

The experiment was conducted at room temperature. Four different random locations on the indium sheet were probed. FIG. 3 shows the results of this testing. As can be seen, only about 0.4 N (0.1 lb_{f}) is required to displace the solder by about 0.203 to 0.229 mm (about 8 to 9 mils). Similarly, only about 1.1 N (0.25 lb_{f}) is required to displace the solder about 0.5 mm (about 20 mil). Since adequate electrical contact is expected to occur at approximately 0.125 mm (about five (5) mils), these test results clearly show that indium solder is easily penetrable and provides a good material choice for the soft solder of the present invention. In comparison, conventional tin-based solder used in solder bumps is not as easily penetrated, requiring up to five times the amount of force to obtain a similar displacement. Furthermore, there is no concern regarding premature release of the contact between the solder and spring element, as there is additional force being provided constantly to the package via a clamping mechanism, i.e., compressive force apparatus, as described above.

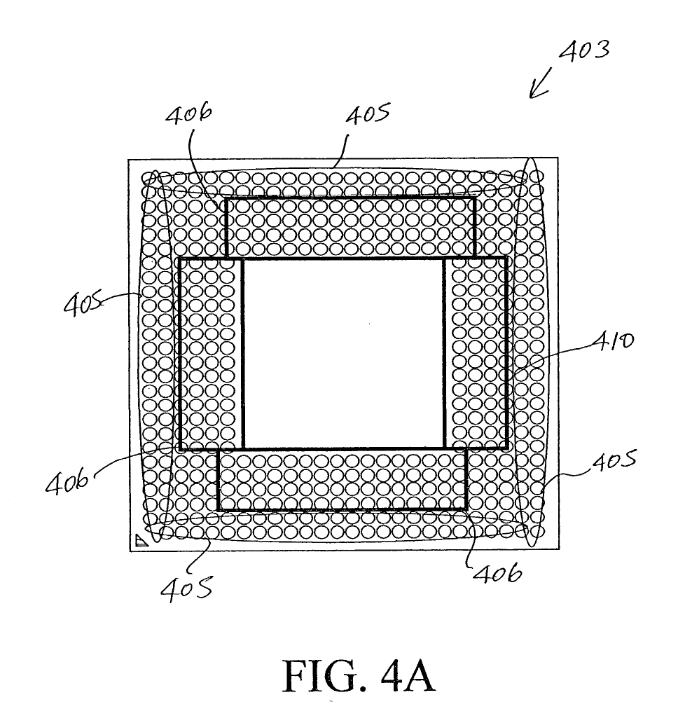

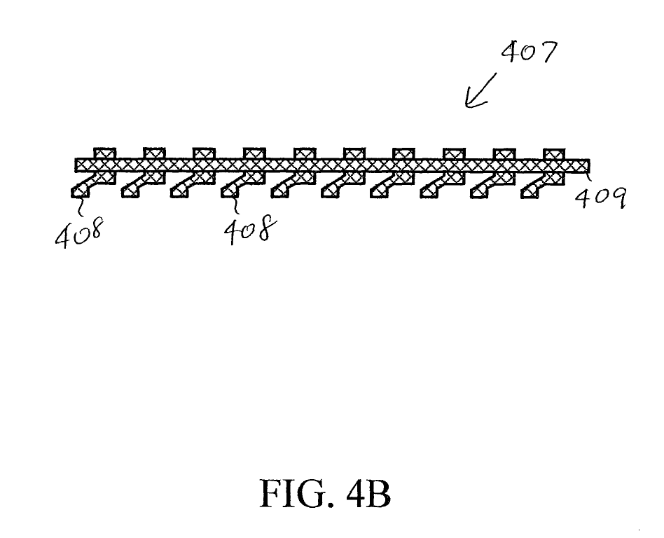

It is further possible to design spring contact elements to function as a unit for use with modified package pads. FIG. 4A is a schematic illustration of a socketless package pad 403 useful with the spring contact unit shown below in FIG. 4B. The socketless package pad 403 in FIG. 4A has an interconnected arrangement of bumps, with power bumps 406 and ground bumps 410 grouped together into specific areas. Specifically, the pad 403 contains input/output (I/O) bumps 405, which transfer an electrical pulse between a central processing unit (CPU) located in a package (not shown) and circuit board (not shown) on a constant basis, as is known in the art. Power bumps 406 serve to maintain the central processing unit (CPU) in a constant state by maintaining a constant DC current. Ground bumps 410 also provide a constant voltage ratio with no signal exchange.

The configuration shown in FIG. 4A provides advantages during manufacturing as the I/O bumps 405, power bumps 406 and ground bumps 410 can be constructed from a single piece of sheet metal. In this way, the entire pad 403 can be surface mounted onto a package as a unit, rather than as individual bumps. Such a configuration also has advantages during use. Specifically, this arrangement serves to reduce DC resistance, thus enhancing power performance. Essentially, since power bumps 406 and ground bumps 410 are being grouped together in specific areas, there is now a bigger cross-section through which current can pass, thereby allowing more current to be carried. The actual overall improvement obtained will be dependent on the number of I/O bumps 403 needed for any given application. However, it is expected that the current-carrying capability will be increased more than about ten times with this configuration.

FIG. 4B is a schematic illustration of a spring contact element strip 407 useful with the socketless package pad 403 of FIG. 4A. The principles for the spring contact elements discussed in FIG. 2 remain the same, although in this embodiment, rather than using individual spring elements, several such elements 408 are connected to a single metal strip 409. In another embodiment, the elements and strip are integral with one another. Similar advantages exist for manufacturing of such a strip 407 as for the package pad 403 in FIG. 4A, in that strips of any desired length can now be produced from sheet metal and then cut to size. By merging multiple power bumps and/or ground bumps and/or I/O bumps into a larger plane, the metallic spring element/package design shown in FIGS. 4A-4B can essentially alleviate the limitations in electric current-carrying capability in the existing package/socket design.

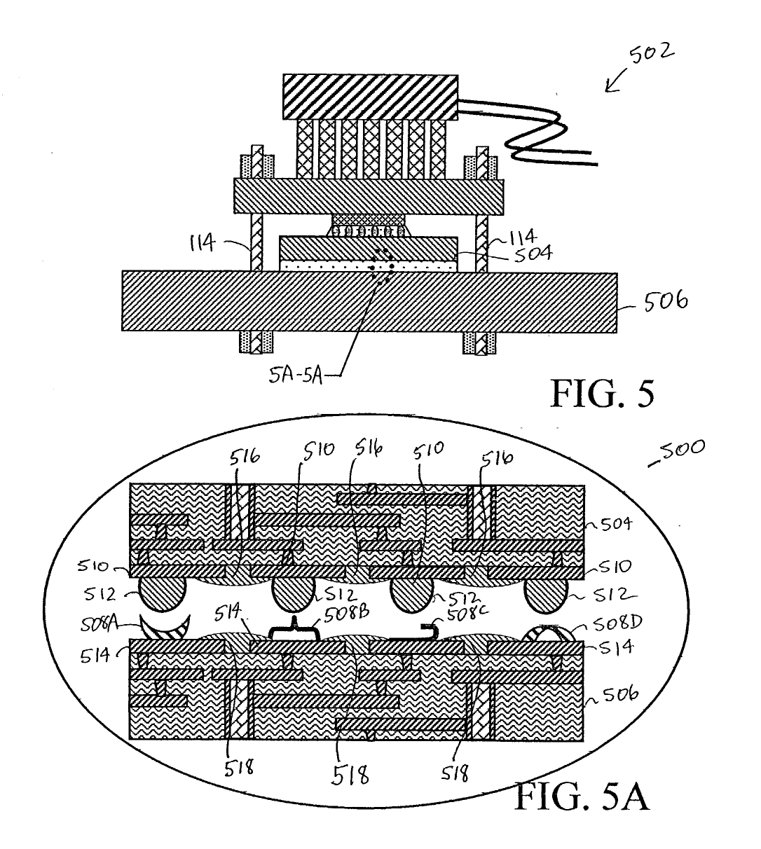

FIGS. 5 and 5A show schematic illustrations of several different socketless FCBGA package to printed circuit board direct contact assemblies 500 (hereinafter “alternative direct contact assemblies”). As FIG. 5 shows, the alternative direct contact assemblies 500 are part of a printed circuit assembly 502. Unlike the assembly 200 in FIGS. 2 and 2A, however, the alternative direct contact assemblies 500 in this embodiment utilize soft solder areas 512 on the package pads 510 and spring contact elements (508A-508D) on the circuit board pads 514. Additionally, the soft solder areas 512 in this embodiment are more spherical in shape than in the other embodiments shown herein, although the invention is not so limited. The spherical configuration is achieved through conventional ball grid array package assembly techniques known in the art.

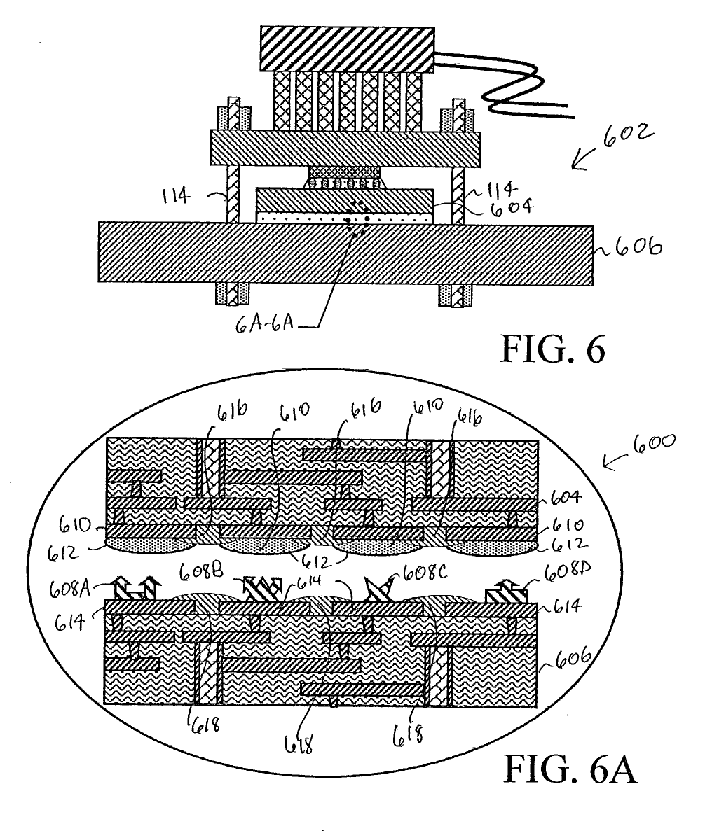

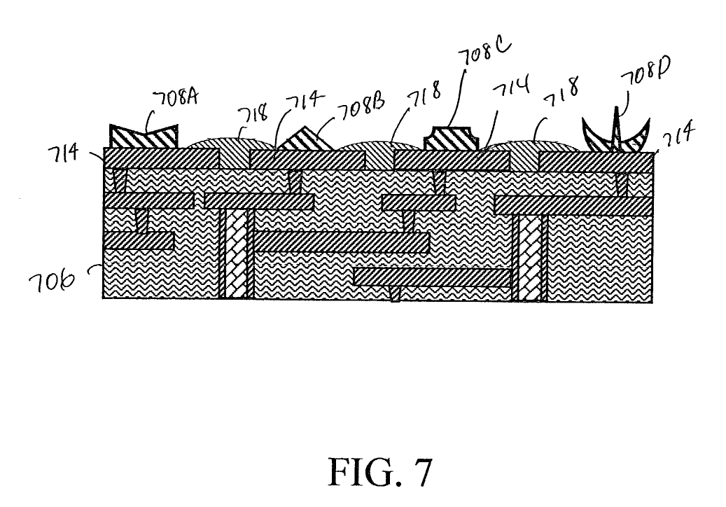

Use of a variety of designs for the spring contact elements 508A-508D is for exemplary purposes only, and in most embodiments, one type of design will be used for a given package, although the invention is not so limited. Furthermore, the spring contact elements 208 of FIG. 2A as well as the sharp metallic elements shown below in FIGS. 6A and 7 can also be used with the soft solder areas 512 shown. In one embodiment, a convex-shaped spring 508A is used as it provides a large contact area. As in the other embodiments, the additional compressive pressure applied through bolt joints 114 (or alternative clamping mechanism, heat sink clips, etc.) enhances the robustness of the system performance in use.

FIGS. 6 and 6A show schematic illustrations of several different socketless FCLGA package to printed circuit board direct contact assemblies 600 using sharp metallic contact elements 608A-608D rather than spring contact elements. Again, the various types of sharp metallic contact elements (608A-608D) shown on the circuit board 606 are shown for exemplary purposes only. In most embodiments, the sharp metallic contacts on any one circuit board would be the same, although the invention is not so limited. In an alternative embodiment, any combination of spring contact elements and/or sharp metal contacts can be used additionally or alternatively to the sharp metal contacts. Similarly, any suitable type of soft solder material and bump geometry can also be used with the sharp metallic contact elements 608A-608D.

In this embodiment, the sharp metallic elements 608A-608D are built onto the motherboard pads 614, although the invention is not so limited. In another embodiment, the sharp metallic contact elements are located on the package pads 610, with the solder areas 612 then located on the motherboard package pads 614. Additionally, the conventional package solder resist coating 616 and motherboard solder resist coating 618 are present to mask off and surface insulate certain areas of the circuit as described herein. The sharp metallic elements 608A-608D can be made from any suitable conductive material, including all of the materials noted above for the spring contact elements and can further include a resilient plating, such as gold plating.

FIG. 7 shows additional possible configurations for the sharp metallic contact elements, i.e., 708A-708D built onto circuit board pads 714. Conventional solder resist coatings 716 and 718 are also present in between the package pads 710 and circuit board pads 714, respectively. It should be noted that any suitable sharp metallic contact element can also be used with the strip configuration and modified package pad shown in FIGS. 4A and 4B.

Virtually, any design or shape can be used for the metallic contact elements, i.e., either the spring contact elements or the sharp metallic contact elements, as long as they are capable of penetrating the opposing soft solder areas sufficiently to provide a secure electrical contact. Similarly a sufficient amount and type of soft solder must be used so that the contact element can penetrate it by at least 5 mils. By combining the sharp metallic features and/or spring designs of the present on either the circuit board or package, an adequate amount of soft solder to the opposing surface, together with adequate compressive force, a package can now be directly assembled onto a circuit board without use of an OEM socket or surface mount reflow process, thus ensuring appropriate electrical contact and thermal performance.

The direct package to motherboard design described herein provides several competitive advantages, including improved electrical performance due to lower resistance and/or inductance. By eliminating the need for a socket, the design further provides reduced overall system build of material cost as well as minimizing OEM and customer inventory and/or import tariff costs. Additionally, the growing problem of performance limitation due to finer pitch surface mounted socket developments associated with sockets is virtually eliminated.

The direct contact assemblies of the present invention have the additional advantage of being removable. In this way, when an end user desires to upgrade to a different CPU, it is now possible to obtain a replacement package at a retail outlet and mount the new package to the existing circuit board. The actual replacing can be performed either by a skilled technician or an advanced end-user. This is most practical when the receiving feature (i.e., the contact element) is built onto the circuit board. The flexibility provided with this readily demountable configuration is in contrast to surface-mounted components that are permanently mounted to the circuit board, thus requiring replacement of the entire circuit board when upgrading the package. Such an advantage provides considerable cost savings to the end user.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. Therefore, it is manifestly intended that this invention be limited only by the claims and the equivalents thereof.

What is claimed is:

1. An apparatus comprising:
a socketless package having a package pad, the package pad having a metallic contact element secured thereto and adapted to penetrate a solder area sufficiently to create an electrical contact, the solder area located on a circuit board pad.

2. The apparatus of claim 1 further comprising a compressive force apparatus adapted to removably hold the package pad and circuit board pad together.

3. The apparatus of claim 2 wherein the apparatus further comprises a thermal solution.

4. The apparatus of claim 3 wherein the thermal solution is a heat sink or a heat pipe.

5. The apparatus of claim 2 wherein the compressive force apparatus is a bolt joint, thermal solution attach mechanism or clamp mechanism.

6. The apparatus of claim 1 wherein the solder area contains solder having a melting temperature of between about 100 and 220° C.

7. The apparatus of claim 2 wherein the solder is indium.

8. The apparatus of claim 2 wherein the solder is an indium/silver alloy, tin/indium alloy or tin/bismuth alloy.

9. The apparatus of claim 1 wherein the metallic contact element penetrates the solder area by at least about 0.13 mm.

10. The apparatus of claim 9 wherein the solder area and metallic contact element are designed to correct misalignments between the package pad and circuit board pad.

11. The apparatus of claim 10 wherein misalignments up to about 25 mil can be corrected.

12. The apparatus of claim 1 wherein the metallic contact element is made from copper, copper alloys, nickel/iron alloys or silver alloys.

13. The apparatus of claim 12 wherein the metallic contact element further has a metallic coating.

14. The apparatus of claim 13 wherein the metallic coating is gold plating.

15. The apparatus of claim 13 wherein the metallic contact element is a sharp contact element.

16. The apparatus of claim 13 wherein the metallic contact element is a spring.

17. The apparatus of claim 16 wherein the spring has a spring constant of between about 35 and 52.5 Newtons (N)/cm.

18. The apparatus of claim 1 wherein the circuit board is a motherboard.

19. The apparatus of claim 1 wherein the socketless package is a ball grid array package, a pin grid array package or a land grid array package.

20. The apparatus of claim 19 wherein resistance in the socketless package is less than 10 milliohms.

21. An apparatus comprising:
a socketless package having a package pad, the package pad having a solder area located thereon, the socket area penetrable by a metallic contact element sufficiently to create an electrical contact between the solder area and the metallic contact element, wherein the metallic contact element is located on a circuit board pad.

22. The apparatus of claim 21 wherein the metallic contact element is a sharp contact element or a spring, the metallic contact element having metallic plating.

23. The apparatus of claim 22 wherein the solder area contains solder having a melting point of between about 100 and 220° C. and a yield strength of five (5) to 25 MPa.

24. An apparatus comprising a socketless package to circuit board assembly, the assembly including a solder area and an opposing metallic element, wherein the metallic element can penetrate the solder area sufficiently to create an electrical contact.

25. The apparatus of claim 24 wherein the solder area is located on a circuit board and the metallic element is located on a package.

26. The apparatus of claim 24 wherein the solder area is located on a package and the metallic element is located on a circuit board.

27. The apparatus of claim 24 further comprising:
a heat sink located adjacent to the package; and
a compressive force apparatus securable to the heat sink and circuit board, the compressive force apparatus adapted to removably hold the assembly together.

28. An assembly comprising:
a solder area deposited on a first pad, the solder area containing solder having a melting temperature of between about 100 and 220° C.; and
a metallic contact element connected to a second pad, the metallic contact element adapted to penetrate the solder area sufficiently to create an electrical interconnection.

29. The assembly of claim 28 wherein the first pad is located on a motherboard and the second pad is located on a package.

30. The assembly of claim 28 wherein the first pad is located on a package and the second pad is located on a motherboard.

31. The assembly of claim 28 further comprising a compressive force apparatus adapted to removably hold the solder deposit and metallic element together.

32. A package comprising:
a metallic contact element strip containing a plurality of metallic contact elements adapted to penetrate a plurality of solder areas sufficiently to create electrical contacts, each solder area having solder with a melting temperature of between about 100 and 220° C.

33. The package of claim 32 wherein the plurality of solder areas are located on a series of power bumps and ground bumps, the power bumps and ground bumps each grouped into at least one area in the package, the package designed to carry up to ten times more current.

34. The package of claim 33 wherein the metallic contact strip is located on a circuit board.

35. The package of claim 33 wherein the metallic contact elements are spring contact elements.

36. A method comprising:
substantially aligning a first pad and a second pad, the first pad coated with soft solder and the second pad having a metallic contact element built thereon;
joining the soft solder and metallic contact element together wherein the metallic contact element penetrates the soft solder sufficiently to create an electrical contact;
clamping the first pad and second pad together with a compressive force apparatus wherein a package is temporarily assembled directly on a circuit board.

37. The method of claim 36 wherein the first pad is located on the circuit board and the second pad is located on a package.

38. The method of claim 36 wherein the first pad is located on a package and the second pad is located on the circuit board.

39. The method of claim 36 further comprising:
removing the package from the circuit board; and
replacing the package with another package.
